(19) United States
(12) Patent Application Publication
(10) Pub. No.: US 2008/0197343 A1
(43) Pub. Date: Aug. 21, 2008

(54) Organic Field Effect Transistor Gate

(76) Inventors: Robert Blache, Hochstadt (DE); Walter Fix, Nurnberg (DE); Jurgen Ficker, Erlangen (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 11/721,244

(22) PCT Filed: Dec. 6, 2005
(86) PCT No.: PCT/DE05/02195

§ 371 Date: Aug. 6, 2007

(30) Foreign Application Priority Data
Dec. 10, 2004 (DE) 10 2004 059 467.8

(51) Int. Cl. H01L 51/05; H01L 51/40

(52) U.S. Cl. 257/40; 438/99; 257/E51.005

(57) ABSTRACT

An electronic device, in particular an RFID transponder, comprises at least one logic gate, in which the logic gate is formed from a plurality of layers, which are applied on a common substrate, which layers comprise at least two electrode layers and at least one of the layers, in particular an organic layer, forms a semiconductor layer which is applied as a liquid, and an insulator layer and wherein the logic gate comprises at least two differently constructed field effect transistors. The field effect transistors are formed from a plurality of functional layers applied to a carrier substrate by printing or blade coating.

The invention relates to an electronic device, in particular an RFID transponder, comprising at least one logic gate formed from organic field effect transistors.

The simplest logic gate is the inverter, from which all complex logic gates, such as, for example, ANDs, NANDs, NORs and the like, can be formed by combination with further inverters and/or further electronic components. Organic logic gates comprising only one type of semiconductor—p-type semiconductors are typically involved—as active layer are susceptible to parameter fluctuations of the individual devices. This can mean that said circuits operate unreliably or do not operate at all as soon as individual devices, such as transistors, cannot adequately fulfill the specifications determined by the circuit design on account of deviations in the production process. Moreover, a dissipative current, that is to say a current that does not stem from the function of the circuit, flows in these circuits based only on one type of semiconductor, depending on the circuit concept used, at least during half of the operating time. As a result, the power consumption is significantly higher than is actually necessary.

Such logic gates are unsuitable for RFID transponders (RFID=Radio Frequency Identification), for example, since the RFID transponders obtain their supply voltage from a radiofrequency signal that is received by means of a small antenna and then rectified. RFID transponders are increasingly being employed for providing merchandise or security documents with information that can be read out electronically. They are thus being employed for example as electronic bar code for consumer goods, as luggage tag for identifying luggage or as security element that is incorporated into the binding of a passport and stores authentication information.

The document KLAUK, H. et al.: Pentacene Thin Film Transistors and Inverter Circuits. In: IEDM Tech. Dig., December 1997, pp. 539-542, describes an inverter comprising organic field effect transistors of identical type, which is formed from a charging field effect transistor and a switching field effect transistor, which transistors are connected in series. The production of the field effect transistors is provided by thermal deposition of the organic semiconductor material.

Combinations of different semiconductors for logic gates are also known, but hitherto only organic semiconductors have been combined with inorganic semiconductors, for example described in the document BONSE, M. et al.: Integrated a-Si:H/Pentacene Inorganic/Organic Complementary Circuits. In: IEEE IEDM 98, 1998, pp. 249-252, or organic semiconductors have been combined with organometallic semiconductors, as reported in the document CRONE, B. K. et al,: Design and fabrication of organic complementary circuits. In: J. Appl. Phys. Vol. 89, May 2001, pp. 5125-5132. Thermal deposition of the organic semiconductor is likewise provided as the production method for the field effect transistors in both documents.

It is an object of the present invention to specify an improved electronic device using field effect transistors.

This object is achieved according to the invention by forming an electronic device comprising at least one logic gate, wherein the logic gate is formed from a plurality of layers which are applied on a common substrate, which comprise at least two electrode layers at least one, in particular organic, semiconductor layer applied from a liquid, and an insulator layer and which are formed in such a way that the logic gate comprises at least two differently constructed field effect transistors.

In this case, the term liquid encompasses for example suspensions, emulsions, other dispersions or else solutions. Such liquids can be applied by printing methods, for example, wherein parameters such as viscosity, concentration, boiling point and surface tension determine the printing behavior of the liquid. Field effect transistors are understood hereinafter to mean field effect transistors whose semiconductor layers have essentially been applied from said liquids.

By forming two, in particular, organic, field effect transistors which differ in terms of their construction on a common carrier with at least one semiconductor layer applied from liquid, it is possible to form logic gates having properties which cannot be obtained otherwise.

In this way, it is possible to realize faster logic gates than by means of the previous embodiment with only one semiconductor. Thus, to date it has been conventional practice to construct circuits based on only one type of semiconductor on a carrier, that is to say that silicon-based ICs have only silicon-based transistors. The invention makes it possible to simplify the circuit design, to increase the switching speed, to reduce the power consumption and/or to increase the reliability. At the same time it is therefore ensured that this type of logic gate can be produced by means of fast and continuous production methods, for example in a roll-to-roll printing method. The logic gates according to the invention are furthermore distinguished by greater insensitivity toward production tolerances. A further advantage of the logic gates according to the invention is their lower power consumption by comparison with conventional, in particular organic, logic gates.

Therefore, the circuit layout no longer has to be developed in a manner taking account of reserves, such as, for example, by overdimensioning the individual devices or by inserting redundant components.

The organic field effect transistor, referred to hereinafter as OFET, is a field effect transistor comprising at least three electrodes and an insulating layer. The OFET is arranged on a carrier substrate, which may be formed as a solid substrate or as a film, for example as a polymer film. A layer composed of an organic semiconductor forms a conductive channel, the end sections of which are formed by a source electrode and a drain electrode. The layer composed of an organic semiconductor is applied from a liquid. The organic semiconductors may be polymers dissolved in the liquid. The liquid containing the polymers may also be a suspension, emulsion or other dispersion.

The term polymer here expressly includes polymeric material and/or oligomeric material and/or material composed of “small molecules” and/or material composed of “nanoparticles”. Layers composed of nanoparticles can be applied by means of a polymer suspension, for example. Therefore, the polymer may also be a hybrid material, for example in order to form an n conducting polymeric semiconductor. All types of substances with the exception of the traditional semiconductors (crystalline silicon or germanium) and the typical metallic conductors are involved. A restriction in the dogmatic sense to organic material within the meaning of carbon chemistry is accordingly not intended. Rather, silicones, for example, are also included. Furthermore, the term is not intended to be restricted with regard to the molecular size, but rather to include “small molecules” or “nanoparticles”, as already explained above. Nanoparticles comprise organometallic semiconductor-organic compounds containing zinc oxide, for example, as non-organic constituent. It may be provided that the semiconductor layers are formed with different organic materials.

The conductive channel is covered with an insulation layer, on which a gate electrode is arranged. The conductivity of the channel can be altered by application of a gate-source voltage U_{GS} between gate electrode and source electrode. The semiconductor layer may be formed as a p-type conductor or as an n-type conductor. The current conduction in a p-type conductor is effected almost exclusively by defect electrons, and the current conduction in an n-type conductor is effected almost exclusively by electrons. The prevailing charge carriers present in each case are referred to as majority carriers. Even though p-type doping is typical of organic semiconductors, it is nevertheless possible to form the material with n-type doping. Pentacene, polyalkylthiophene, etc. may be provided as p-conducting semiconductors, and e.g. soluble fullerene derivatives may be provided as n-conducting semiconductors.

The majority carriers are densified by the formation of an electric field in the insulation layer if a gate-source voltage UGS of suitable polarity is applied, that is to say a negative voltage in the case of p-type conductors and a positive voltage in the case of n-type conductors. The electrical resistance between the drain electrode and the source electrode consequently decreases. Upon application of a drain-source voltage UGS, it is then possible for a larger current flow to form between the source electrode and the drain electrode than in the case of an open gate electrode. A field effect transistor is therefore a controlled resistor. The logic gate according to the invention, through combination of two differently formed field effect transistors, in particular OFETs, then avoids the disadvantage of combinations of field effect transistors of identical type, in particular OFETs, of forming a dissipative current, i.e. exhibiting a current flow when they are not driven.

Advantageous embodiments of the invention are presented in the subclaims.

It is provided that the at least two different field effect transistors have semiconductor layers which differ in terms of their thickness. The formation of the different thicknesses may be provided by means of semiconductors formed in soluble fashion, advantageously in a printing process. For this purpose, in the case of organic semiconductors, provision may be made for varying the polymer concentration of the semiconductor. In this way, a layer thickness of the organic semiconductor that is dependent on the polymer concentration is formed after the evaporation of the solvent.

It may also be provided that the semiconductor layers of the field effect transistors are formed with different conductivities. The conductivity of the, in particular organic, semiconductor layer can be decreased or increased for example by means of a hydrazine treatment and/or by targeted oxidation. The field effect transistor formed with such a semiconductor material can thus be set in such a way that its off currents are only approximately one order of magnitude less than the on currents. The off current is the current which flows in the field effect transistor between source electrode and drain electrode if no electrical potential is present at the gate electrode. The on current is the current which flows in the field effect transistor between source electrode and drain electrode if an electrical potential is present at the gate electrode, for example a negative potential it a field effect transistor with p-type conduction is involved.

It is therefore advantageous to use different types of semiconductors or to arrange a different combination of semiconductors for forming an electronic functional layer alongside one another, and thus to influence properties such as charge mobility, switching speed and power or switching behavior in a targeted manner.

It may also be provided that the field effect transistors differ in the formation of the insulator layer. They may have insulator layers having different thicknesses and/or different materials. However, the insulator layers of the at least two differently formed field effect transistors may also differ in terms of their permeability and thus influence the charge carrier density that can be formed in the semiconductor layers, or be formed as a dielectric for the capacitive coupling of electrodes, for example for coupling the gate electrode to the source or drain electrode of the same field effect transistor.

The different areal structuring of the layers is possible in a particularly cost-effective manner. This is possible in a particularly simple manner in the case of a printing method, such that in this case the behavior of the field effect transistors can be optimized according to the trial and error method without specifically knowing the functional dependencies. The two different field effect transistors may be formed for example with different channel widths and/or channel lengths. Strip-type structures may preferably be provided. However, arbitrarily contoured structures may also be provided, for example for forming the electrodes of the field effect transistors, such as the gate electrode. The geometrical dimensions are dimensions in the μm range, for example channel widths of 30 μm to 50 μm, tending toward even smaller dimensions in order to obtain high switching speeds and low capacitances between the electrodes. It is known from conventional silicon technology that component capacitances cause high power losses and therefore have a critical influence on minimizing the power demand of the circuit.

In this way, it is also possible to form field effect transistors having different switching capacitances, for example in order to form different switching behaviors.

Provision may be made for arranging the at least two different field effect transistors alongside one another or one above another. In this way, circuit designs can be transferred particularly simply into layouts and the number of plated-through holes, so-called vias, for example, can be minimized. However, the arrangement of the field effect transistors may also be provided for functional reasons, for example in order to form two field effect transistors having a common gate electrode, in which case an arrangement of the two field effect transistors one above another may be particularly advantageous.

The field effect transistors may be arranged with identical orientation or with different orientations. It is provided that the at least two differently formed field effect transistors may be arranged with bottom-gate or top-gate orientation.

Provision may be made for varying the at least two different field effect transistors in such a way that they are formed with a different resistance characteristic curve and/or a different switching behavior. The resistance characteristic curve can be altered for example by changing the thickness of the semiconductor layer, in which case, by forming particularly thin layers—for example in the case of layers within the range of 5 nm to 30 nm—additional effects can be set which cannot be observed given thicker layers of the order of magnitude of 200 nm.

The at least two different field effect transistors may be connected to one another in a parallel and/or series connection. It may be provided, for example, that two differently formed field effect transistors, in particular two OFETS, in series connection form the load OFET and the switching OFET. However, it may also be provided, for example, that load OFET and/or switching OFET are formed by parallel or series connection of two or more different OFETs. In this way, a logic gate formed as an inverter may be formed for example from four—preferably different—field effect transistors. Such logic gates can be connected to form a ring oscillator that can be used, in particular in RFID transponders, as a logic circuit or oscillation generator.

The solution according to the invention is not restricted to the direct electrical coupling of the field effect transistors. Rather, provision may be made for capacitively coupling the field effect transistors to one another, for example by enlarging a gate electrode and a further electrode in such a way that together with the insulation layer they form a capacitor having a sufficient capacitance owing to the possible very small layer thickness of the insulation layer and, if appropriate, of further layers arranged between the capacitively coupled electrodes, comparatively high capacitance values can be formed despite small electrode areas.

Provision may also be made for forming the different field effect transistors with semiconductor layers of different conduction types, that is to say with p-conducting and n-conducting semiconductor layers. Even though p-conducting semiconductor layers are still preferred for forming OFETS, applying an n-conducting layer is nevertheless not more difficult than applying a p-conducting layer. In this way, p-n junctions can also be formed between the two adjoining layers.

The logic gate according to the invention is formed in such a way that it can essentially be produced by printing (e.g. by intaglio printing, screen printing, pad printing) and/or blade coating. The entire construction is therefore directed at forming layers which form the logic gate in their interaction and which can be structured by means of the two methods mentioned. Tried and tested equipment is available for this, as is provided for example for the producing of is optical security elements. The gates according to the invention can therefore be produced on the same installations.

The differing formation of the field effect transistors can be achieved particularly well if the layers of the at least two different field effect transistors, in particular the OFETs, are formed as printable semiconducting polymers and/or printable insulating polymers and/or conductive printing inks and/or metallic layers.

The thickness of the soluble polymeric layer can be set in a particularly simple manner through its solvent proportion. However, it may also be provided that the thickness of the soluble organic layer can be set through its application quantity, for example if the application of the layer by pad printing or by blade coating is provided. Thicker layers can preferably be formed in this way. As an alternative to this, the layered construction of a layer may be provided. If, by way of example, the at least two different field effect transistors have a semiconductor layer of identical material with different thicknesses, the thin layer of one field effect transistor can be applied in a first pass and this basic layer can be reinforced for the other field effect transistor in one or more further passes. For this purpose, provision may be made for applying the layers with different solvent proportions, i.e. the basic layer with a high solvent proportion and the further layer or the further layers with a low solvent proportion.

It may preferably be provided that the electronic device produced in the manner described above is formed by a multilayer flexible film body. The flexibility of the electronic device can make it particularly resistant, in particular if it is applied to a flexible support. The organic electronic devices formed according to the invention as multilayer flexible film bodies are, moreover, completely insensitive to impact loads and, in contrast to devices applied on rigid substrates, can be used in applications in which printed circuit boards are provided which nestle against the contour of the electronic apparatus. There is an increasing trend toward providing these for apparatuses having irregularly formed contours, such as mobile phones and electronic cameras.

Provision may be made for forming security elements, merchandise labels or tickets with one or a plurality of logic gates according to the invention.

The invention will now be explained in more detail with reference to the drawings, in which:

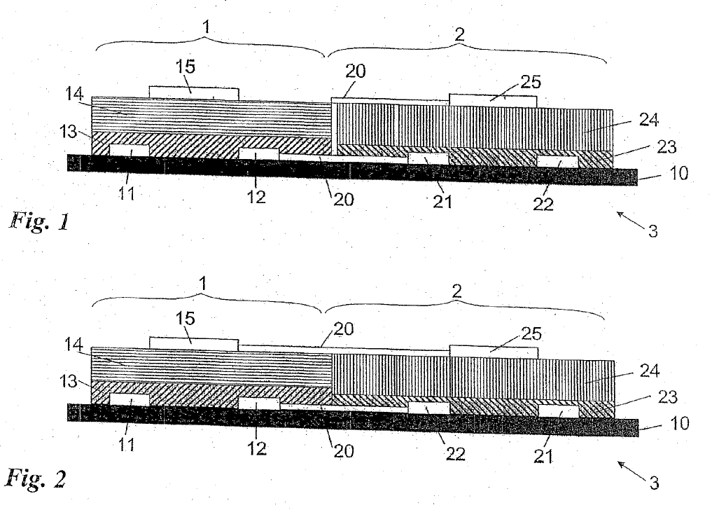

FIGS. 1 and 2 show schematic sectional illustrations of a first exemplary embodiment;

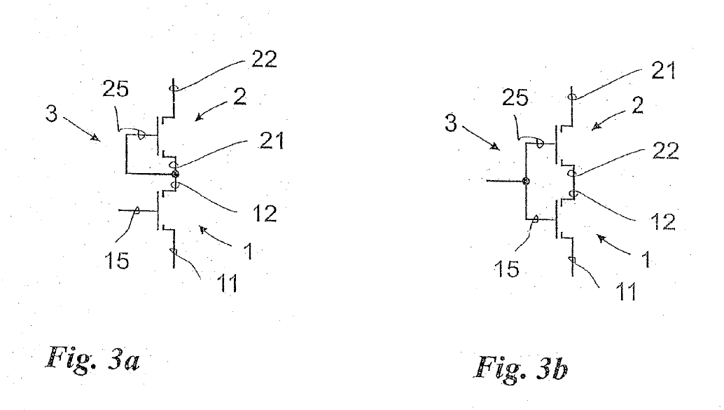

FIGS. 3a and 3b show basic circuit diagrams of the first exemplary embodiments in FIGS. 1 and 2;

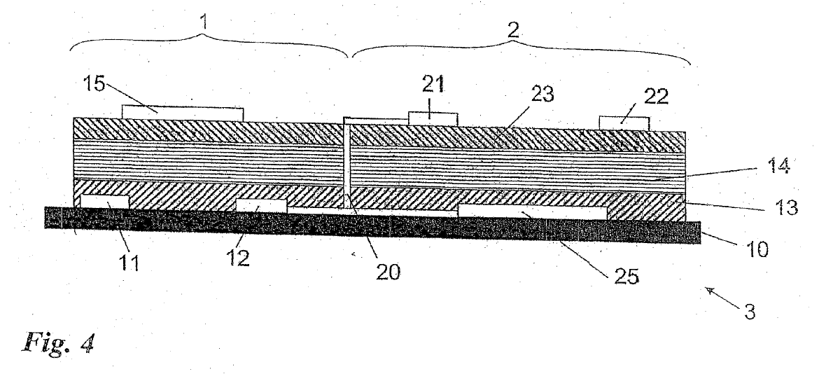

FIG. 4 shows a schematic sectional illustration of a second exemplary embodiment;

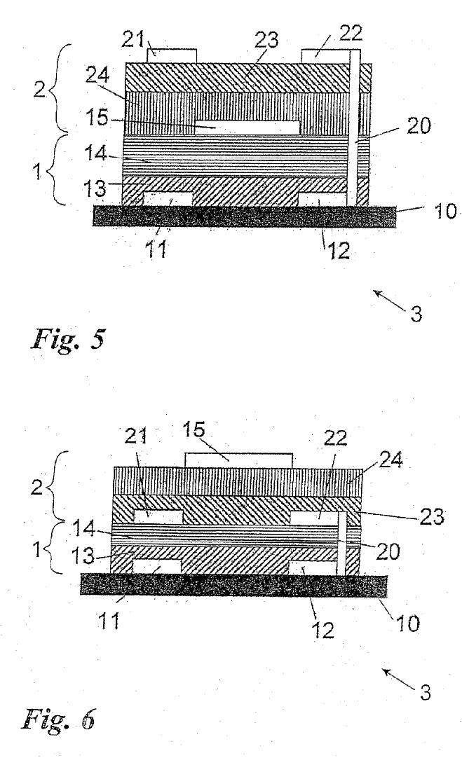

FIG. 5 shows a schematic sectional illustration of a third exemplary embodiment;

FIG. 6 shows a schematic sectional illustration of a fourth exemplary embodiment;

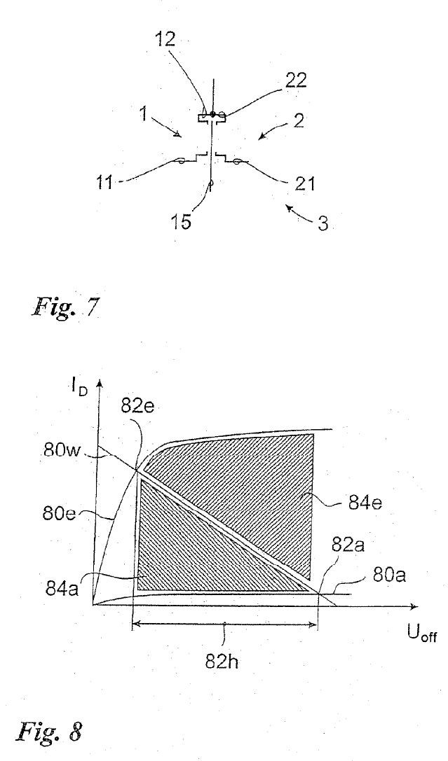

FIG. 7 shows a basic circuit diagram of the exemplary embodiments in FIGS. 5 and 6;

FIG. 8 shows a schematic current-voltage diagram of a logic gate;

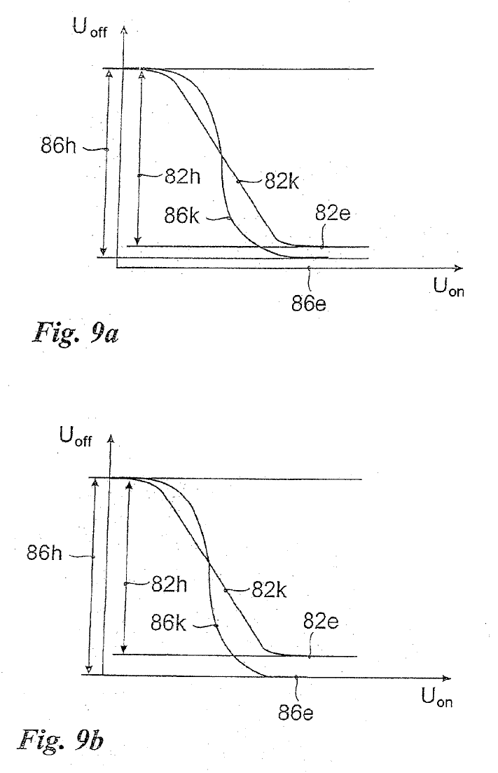

FIG. 9a shows a first schematic output characteristic curve diagram of a logic gate comprising differently formed organic field effect transistors;

FIG. 9b shows a second schematic output characteristic curve diagram of a logic gate comprising differently formed organic field effect transistors.

FIGS. 1 and 2 in each case show a schematic sectional illustration of a logic gate 3, formed from two differently formed organic field effect transistors 1, 2, referred to hereinafter as OFET, which are arranged on a substrate 10. However, field effect transistors which are not formed, or not completely formed, from organic semiconductor material may also be involved in this case. The substrate may be for example a laminar substrate or a film. The film is preferably a plastic film having a thickness of 6 μm to 200 μm, preferably having a thickness of 19 μm to 100 μm, preferably formed as a polyester film.

The first OFET 1 is formed from a first semiconductor layer 13 with a source electrode 11 and a drain electrode 12. An insulator layer 14 is arranged on the semiconductor layer 13 with a gate electrode 15 arranged on said insulator layer.

These layers can be applied in an already partially structured manner, or in a manner structured in patterned fashion, by means of a printing method for example. For this purpose, provision is made for applying in particular the semiconductor layer from a liquid. In this case, the term liquid encompasses for example suspensions, emulsions, other dispersions or else solutions. For preparing solutions, the organic materials provided for the layers are formed as soluble polymers, where the term polymer here, as already described further above, also includes oligometers and “small molecules” and nanoparticles. The organic semiconductor may be for example pentacene. A plurality of parameters of the liquid can be varied:
the viscosity of the liquid, it determines the printing behavior;
the polymer concentration of the mixture ready for printing, it determines the layer thickness;
the boiling point of the liquid, it determines which printing method can be used;
the surface tension of the mixture ready for printing, it determines the wettability of the carrier substrate or other layers.

Provision may also be made, as described in detail further above, for forming the layers with a variable layer thickness by means of repeatedly successive printing.

Provision may also be made for applying to the substrate 10 a curable resist and structuring the latter prior to curing in such a way as to form depressions into which, by way of example, semiconductor layers are introduced by blade coating. Such method steps may be provided in order to combine for example optical security elements produced using curable resist layers with the logic gates according to the invention.

The electrodes 11, 12 and 15 preferably comprise a conductive metallization, preferably composed of gold or silver. However, provision may also be made for is forming the electrodes 11, 12 and 15 from an inorganic electrically conductive material, for example from indium tin oxide, or from a conductive polymer, for example polyaniline or polypyrrole.

The electrodes 11, 12 and 15 may in this case be applied in a manner already partially structured in patterned fashion to the substrate 10 or to the organic insulator layer 14, or another layer provided in the production method, for example by means of a printing method (intaglio printing, screen printing, pad printing) or by means of a coating method. However, it is also possible for the electrode layer to be applied to the substrate 10, or another layer provided in the production method, over the whole area or over a partial area and then to be partially removed again and thus structured by means of an exposure and etching method or by ablation, for example by means of a pulsed laser.

The electrodes 11, 12 and 15 are structures in the μm range. The gate electrode 15, for example, may have a width of 50 μm to 1000 μm and a length of 50 μm to 1000 μm. The thickness of such an electrode may be 0.2 μm or less.

The second OFET 2 is formed from a first organic semiconductor layer 23 with a source electrode 21 and a drain electrode 22. An organic insulator layer 24 is arranged on the organic semiconductor layer 23 of the gate electrode 25 arranged on said insulator layer.

In FIG. 1, the drain electrode 12 of the first OFET 1 is connected to the source electrode 21 of the second OFET 2 and to the gate electrode 25 of the second OFET 2 by means of the electrically conductive connecting layers 20.

Furthermore, it is also possible for the gate electrode 25 to be connected to the drain electrode 22 instead of to the source electrode 21.

In FIG. 2, the gate electrode 15 of the first OFET 1 and the gate electrode 25 of the second OFET 2 and also the drain electrode 12 of the first OFET 1 and the drain electrode 22 of the second OFET 2 are connected by means of electrically conductive connecting layers 20.

In these exemplary embodiments in accordance with FIGS. 1 and 2, the two OFETs 1, 2 lie alongside one another with identical orientation, that is to say that, by way of example, the gate electrodes 15, 25 are arranged in one plane. In the case illustrated, the top-gate orientation is chosen for both OFETs, in other words the two gate electrodes 15, 25 are formed as the topmost layer. However, it may also be provided that the bottom-gate orientation is chosen for both OFETs, in which orientation the two gate electrodes 15, 25 are arranged directly on the substrate 10.

As can be discerned in FIG. 1 and FIG. 2, the organic semiconductor layers 13, 23 determining the electrical properties of the two OFETs 1, 2 and/or the organic insulator layers 14, 24 can be formed with different layer thicknesses, both OFETs 1, 2 being formed with the same overall layer thickness in the exemplary embodiment illustrated. It may preferably be provided that the organic semiconductor layers 13, 23 are applied in strips. In order to form different electrical behaviors of the two OFETs 1, 2, provision may be made for forming differently the thickness and/or the channel length, i.e. the distance between the source electrode 11, 21 and the drain electrode 12, 22, and/or the material of the organic semiconductor layers 13, 23 of the two OFETs 1, 2. The material of the organic semiconductor layers 13, 23 may for example be doped identically or to different extents. The semiconductors layers 13, 23 may be formed as p-type conductors or as n-type conductors. The current conduction in a p-type conductor is effected almost exclusively by defect electrons, and the current conduction in an n-type conductor is effected almost exclusively by electrons. The prevailing charge carriers present in each case are referred to as majority carriers. Even though p-type doping is typical of organic semiconductors, it is nevertheless possible to form the material with n-type doping. Thus, by way of example the p-conducting semiconductor may be formed from pentacene, polythiophene, and the n-conducting semiconductor may be formed for example from polyphenylenevinylene derivatives or fullerene derivatives.

If both organic semiconductor layers 13, 23 have different majority charge carriers, a logic gate 3 comprising semiconductor layers 13, 23 having complementary conductivities is formed. Such a gate is illustrated in FIG. 2, for example, and is distinguished by the fact that a respective one of the two field effect transistors permits no current flow between source and drain as long as the input voltage of the logic gate does not change, that is to say that the gate assumes one of its two switching states. A dissipative shunt current through the gate flows only during the switching operation. Consequently, logic circuits comprising the logic gates according to the invention have a significantly lower current consumption than logic circuits which are formed from identical OFETs. This is particularly advantageous if only current sources having low loading capacity are available, as is the case for example in RFID transponders that obtain their energy from a rectified antenna signal stored in a capacitor.

FIGS. 3a and 3b show the two basic circuits that can be produced with the first exemplary embodiment in FIGS. 1 and 2. The positions in FIGS. 1 and 2 have been maintained for the sake of better illustration.

FIG. 3a shows a logic gate 3, formed from two different OFETs 1 and 2 having semiconductor layers of the same conduction type. The two OFETs 1, 2 are connected in series, the drain electrode 12 of the first OFET 1 being connected to the source electrode 21 of the second OFET 2. The gate electrode 15 of the OFET 1 forms the input of the logic gate, and the gate electrode 25 of the OFET 2 is connected to the source electrode 21 of the OFET 2. The logic gate may be an inverter comprising load OFET 2 and switching OFET 1.

FIG. 3b shows a logic gate 3, formed from two different OFETs 1 and 2 of differing doping types. Such a logic gate, as described further above, is formed with a lower power consumption than an OFET logic gate according to the prior art. The two OFETs 1 and 2 are connected in series, the drain electrode 12 of the first OFET 1 being connected to the drain electrode 22 of the second OFET 2. The gate electrodes 15 and 25 of the two OFETs are connected to one another and represent the input of the logic gate.

FIG. 4 then shows a second exemplary embodiment, in which the two OFETs 1, 2 are arranged alongside one another with different orientations on the substrate 10. In this case, the first OFET 1 is arranged in such a way that the source electrode 11 and the drain electrode 12 are arranged directly on the substrate 10 and are successively followed by the semiconductor layer 13, the insulator layer 14, the second semiconductor layer 23, which is different from the first semiconductor layer, and the gate electrode 15. Such an orientation of the OFET is referred to as top-gate orientation. The second OFET 2 is arranged, then, in such a way that the gate electrode 25 is arranged on the substrate 10 and the source electrode 21 and the drain electrode 22 are arranged such that they lie at the top on the OFET 2. Such an orientation is referred to as bottom-gate orientation. The gate electrode 25 of the OFET 2 is connected to the source contact 21 of OFET 2 and the drain contact 12 of OFET 1 by means of the electrically conductive connecting layer 20, which, in this exemplary embodiment, is formed in sections as a plated-through hole running perpendicular to the substrate 10.

In the exemplary embodiment illustrated it may preferably be provided that the electrodes arranged in a plane in each case are formed from identical material, for example from a conductive printing ink or from a metal layer applied by sputtering, electroplating or vapor deposition. However, it may also be provided that they are formed from different materials in each case, preferably if this is associated with an advantageous functional effect.

In the exemplary embodiment illustrated in FIG. 4, the semiconductor layers 13 and 23 and the insulator layer 14 are formed as layers common to both the OFETs 1, 2. In this case, for OFET 1 exclusively the semiconductor layer 13 produces the connection between source 11 and drain 12. The conductive channel necessary for the function of the OFET 1 is formed in said semiconductor layer 13 at the interface with the insulator layer 14. For OFET 2, by contrast, exclusively the semiconductor layer 23 produces the connection between source 21 and drain 22. As can readily be discerned in FIG. 4, the OFETs 1, 2 are formed with different geometries, here in particular with different channel lengths. However, it may also be provided that both OFETs 1, 2 are formed with different semiconductor layers and/or insulator layers.

The basic circuits that can be formed with the second exemplary embodiment illustrated in FIG. 4 correspond to the basic circuit illustrated in FIGS. 2a and 2b.

It may be provided that the two OFETs 1, 2 are connected to one another by further connecting lines (not illustrated in FIGS. 2a, 2b) in such a way that they are interconnected or connected to other components in parallel or series connection.

The basic circuit diagram of the exemplary embodiment illustrated in FIG. 4, in which the two OFETs 1, 2 are formed with common semiconductor layers that may be formed as p-type conductors or as n-type conductors, is shown in FIG. 2a.

FIG. 2b shows the basic circuit diagram of a modified exemplary embodiment in comparison with FIG. 4, wherein the two semiconductor layers of the OFETs 1, 2 are formed differently and with complementary conduction types. This case emerges from the drawing in FIG. 4 by the depicted connection 20 exclusively connecting the two gate contacts 15 and 25, while a connection of identical type to the connection 20 is additionally placed between drain contact 22 of OFET 2 and drain 12 of OFET 1.

FIG. 5 shows a third exemplary embodiment, in which the two OFETs 1, 2 are arranged in a manner lying one above the other on the substrate 10 and are formed with a common gate electrode 15. The source electrode 11 and the drain electrode 12 of the first OFET 1 are therefore arranged in a manner lying directly on the substrate 10, and the source electrode 21 and the drain electrode 22 are formed as topmost layer of the OFETs 1, 2 lying one on top of another. The logic gate formed from the two OFETs 1, 2 is therefore constructed from a total of 7 layers. In this case, layers having an identical function may be constructed identically or differently, it being provided that at least one of the layers of a layer pair is formed differently. By way of example, it may be provided that the semiconductor layers 13, 23 are formed with different conduction types (p-type conduction, n-type conduction) and/or different geometries.

The two drain electrodes 12, 22 are connected to the electrical interconnect 20 formed as plated-through hole.

FIG. 6 then shows a fourth exemplary embodiment, in which the two OFETs 1, 2 are arranged in a manner lying one above the other on the substrate 10 and are formed with a common gate electrode 15, but both OFETs 1, 2 are arranged with identical orientation on the substrate. In this case, the common gate electrode 15 is formed as topmost layer of the logic gate, which is formed with 7 layers like the logic gate illustrated in FIG. 5.

In the example illustrated, the source electrode 11 and the drain electrode 12 of the first OFET 1 are arranged as a first layer directly on the substrate 10 and are covered by the semiconductor layer 13. The insulator layer 14 is arranged on the semiconductor layer 13. The second OFET 2 is then arranged with the same orientation and the same layer sequence on the OFET 1, that is to say that the source electrode 21 and the drain electrode 22 are applied on the insulator layer 14 and are covered with the semiconductor layer 23, on which the insulator layer 24 of the OFET 2 is applied. The common gate electrode 15 is arranged thereon as a final layer.

The two drain electrodes 12, 22 are connected by means of the electrically conductive connecting layer 20, which is formed as a plated-through hole.

However, it may also be provided that the arrangement described above is formed in such a way that the common gate electrode 15 is formed as bottom-most layer lying directly on the substrate 10.

Owing to the above-described possibility of rotating the arrangement of the layers forming the logic gate through 180°, a particularly advantageous topology of interconnected logic gates or other components can be formed and in this way it is possible for example to avoid or minimize the number of plated-through holes for connecting the logic gates or components.

FIG. 7 then shows the basic circuit that is possible with the exemplary embodiments illustrated in FIGS. 5 and 6.

The two OFETs 1, 2 form in each case a logic gate comprising a common gate electrode 15 and drain electrodes 12, 22 that are conductively connected to one another. The two source electrodes 11 and 21 form further terminals of the logic gate for supply voltage and ground. The logic gate illustrated in FIG. 7 can be formed differently with regard to the conduction type of the semiconductor layers. Semiconductor layers of identical conduction type or semiconductor layers formed with complementary conduction types may be involved in this case.

FIG. 8 then shows an example of a current-voltage diagram of a logic gate with OFET that is formed as an inverter. A logic gate comprising an OFET can form an inverter in which the source electrode is connected to the circuit ground, the gate electrode forms the input of the inverter and the drain electrode forms the output of the inverter and is connected to the supply voltage via a load resistor. As soon as the gate electrode is then connected to an input voltage, a current flow forms between source electrode and drain electrode, whereby the channel resistance of the OFET is reduced to an extent such that the drain electrode has approximately zero potential. As soon as the input voltage at the gate electrode is then zero, the channel resistance of the OFET rises to such a great extent that the drain electrode has approximately the potential of the supply voltage. In this way, therefore, the input voltage is transformed into an inverted output voltage, that is to say that the input signal of the inverter is inverted. In practice, the load resistor of the inverter is likewise formed as an OFET. For better differentiation, this OFET is referred to as the load OFET and the OFET that effects switching is referred to as the switching OFET.

The current-voltage diagram in FIG. 8 shows the dependence between the forward current I_{D} through switching OFET or load resistor and the output voltage Uₒᵤₜ. In this case, 80e denotes the on characteristic curve and 80a denotes the off characteristic curve of the switching OFET, and 80w denotes the resistance characteristic curve of the load resistor. The points of intersection 82e and 82a of the resistance characteristic curve 80w with the on characteristic curve 80e and with the off characteristic curve 80a denote the switching points of the inverter, which are spaced apart from one another by a voltage swing 82h of the output voltage Uₒᵤₜ. A charge-reversal current flows during each changeover operation of the inverter, the magnitude of said current being symbolized by the hatched areas 84e and 84a. Fast logic gates which can be switched reliably and well at the same time are distinguished by the schematically illustrated properties in FIG. 8 of the large voltage swing 82h and the charge-reversal currents 84e and 84a approximately identical in magnitude.

FIG. 9a qualitatively illustrates a first profile of the output voltage Uₒᵤₜ of the inverter as a function of the input voltage Uᵢₙ. In this case, the curve 82k is to be assigned to the inverter from FIG. 8. The position of the off level 82e is directly dependent on the position of the curves 80e and 80w in FIG. 8. By means of the embodiment according to the invention of the logic gates comprising at least two different OFETs 1, 2, as illustrated in FIG. 2b, for example, the advantageous characteristic curve 86k illustrated in FIG. 9a can be formed for example by forming the two OFETs with semiconductors layers 13, 23 having different thicknesses. The advantage resides in the larger voltage swing 86h that results from this in comparison with 82h.

FIG. 9b shows a second profile of the output voltage Oₒᵤₜ of the inverter as a function of the input voltage Uᵢₙ in a qualitative illustration. The voltage swing 86h is now enlarged again because the characteristic curve 86h includes the output voltage Uₒᵤₜ=0. Such an inverter is formed with a particularly low power loss.

The embodiment of the logic gates according to the invention comprising different field effect transistors which can be produced by layer-by-layer printing and/or blade coating enables the cost-effective mass production of the logic gates according to the invention. The printing methods have reached a state such that extremely fine structures can be formed in the individual layers which can only be formed with a high outlay using other methods.

1. An electronic device comprising:
at least one logic gate comprising a plurality of layers on a common substrate;
the logic gate comprising at least two electrode layers and at least one organic semiconductor layer; and
an insulator layer;
the insulator layer, the at least two electrode layers and the at least one organic semiconductor layer comprising at least two differently constructed field effect transistors arranged to form at least one of the following constructions:
a) the at least two different field effect transistors include corresponding different semiconductor layers which comprise respective different semiconductor material; or
b) the at least two different field effect transistors comprise respective corresponding insulator layers with different respective insulator materials; or
c) the at least two different field effect transistors have respective corresponding electrode layers which comprise different respective electrode materials.

2. The electronic device as claimed in claim 1 wherein the logic gate forms the one construction comprising the at least two differently constructed field effect transistors which include corresponding two different semiconductor material layers which differ in respective thicknesses.

3. The electronic device as claimed in claim 1 wherein the logic gate forms the one construction comprising the at least two differently constructed field effect transistors which comprise respective different semiconductor material layers which differ in respective conductivity.

4. The electronic device as claimed in claim 1 wherein the logic gate forms the one construction comprising the at least two differently constructed field effect transistors in that the at least two different field effect transistors have respective corresponding different respective insulator layers with respective different thicknesses.

5. The electronic device as claimed in claim 1 wherein the logic gate forms the one construction comprising the at least two differently constructed field effect transistors in that the at least two different field effect transistors have respective corresponding insulator layers of different respective permeability.

6. The electronic device as claimed in claim 1 wherein the logic gate is arranged to form the one construction comprising the at least two differently constructed field effect transistors in that the at least two different field effect transistors are formed with differently areally structured layers.

7. The electronic device as claimed in claim 6 wherein the structured layers are formed as strips with different lengths and/or different widths.

8. The electronic device as claimed in claim 1 wherein the at least two different field effect transistors are alongside one another.

9. The electronic device as claimed in claim 1 wherein the at least two different field effect transistors are one above another.

10. The electronic device as claimed in one of claims 8 or 9 wherein the at least two different field effect transistors are in an identical orientation.

11. The electronic device as claimed in claim 10 wherein the at least two different field effect transistors are in a bottom-gate or in a top-gate orientation.

12. The electronic device as claimed in claim one of claims 8 or 9 wherein the at least two different field effect transistors are with different orientations.

13. The electronic device as claimed in claim 1 wherein the at least two different field effect transistors each have a profile of internal resistance and/or switching behavior and wherein the at least two different field effect transistors each have a different profile of its internal resistance and/or a different switching behavior.

14. The electronic device as claimed in claim 1 wherein the at least two field effect transistors are connected to one another in parallel and/or series with each other.

15. The electronic device as claimed in claim 14 wherein the electrical connection between the at least two field effect transistors is one of direct electrical conductive and/or capacitive coupling to and between electrodes of the field effect transistors.

16. The electronic device as claimed in claim 14 wherein the at least two different field effect transistors have are formed with a common gate electrode.

17. The electronic device as claimed in claim 1 wherein the at least two different field effect transistors respectively comprise semiconductor material of complementary conduction types, a the first field effect transistor being formed with a p-conducting semiconductor layer and a second field effect transistor being formed with an n-conducting semiconductor layer, or vice versa.

18. The electronic device as claimed in claim 1 wherein at least two different field effect transistors have directly adjoning semiconductor layers, the directly adjoining semiconductor layers of the at least two different field effect transistors exhibiting a zone with a p/n junction.

19. The electronic device as claimed in claim 1 wherein the at least two different field effect transistors are spatially arranged on a substrate for production via layer-by-layer printing and/or blade coating.

20. The electronic device as claimed in claim 1 wherein the layers of the at least two different field effect transistors comprise printable semiconducting polymers and/or printable insulating polymers and/or conductive printing inks and/or metallic layers.

21. The electronic device as claimed in claim 1 wherein at least one of the layers forming the electronic device comprise a soluble organic layer, including a layers composed of polymeric material and/or oligomeric material and/or material composed of “small molecules” and/or material composed of nanoparticles.

22. The electronic device as claimed in claim 21 wherein the thickness of the soluble organic layer which comprises a proportional amount of a solvent, has a thickness value that corresponds to its solvent proportion.

23. The electronic device as claimed in claim 21 wherein the thickness of the soluble organic layer comprises an application quantity, the thickness having a value corresponding to its application quantity.

24. The electronic device as claimed in claim 1 wherein the plurality of layers forming the logic gate comprise a multilayer flexible film body.

25. The electronic device as claimed in claim 1 including an apparatus of a given contour wherein the electronic device is a flexible electronic circuit attached to the apparatus and wherein the circuit matches the apparatus contour.

26. A method of making an electronic device comprising:
forming on a substrate at least one logic gate comprising at least two differently constructed field effect transistors each comprising at least two electrode layers, at least one organic semiconductor layer, and at least one insulator layer; and
forming the layers into at least two differently constructed field effect transistors by at least one of:
a) forming the corresponding respective semiconductor layers of the at least two different field effect transistors from an applied liquid comprising respective different semiconductor material; or
b) forming the respective corresponding insulator layers of the at least two different field effect transistors from an applied liquid comprising different respective insulator material; or
c) forming the respective corresponding electrode layers of the at least two different field effect transistors with different respective electrode material.

27. The method of claim 26 wherein the liquid in each instance is one of a suspension, an emulsion, a dispersion or solution.

28. The method of claim 26 further including printing the applied liquid on at least one of the substrate and layers.
